(19) United States
(12) Patent Application Publication
(10) Pub. No.: US 2012/0122271 A1
(43) Pub. Date: May 17, 2012

(54) ETCHING METHOD TO INCREASE LIGHT TRANSMISSION IN THIN-FILM PHOTOVOLTAIC PANELS

(75) Inventors: Lap-Tak Andrew Cheng, Newark, DE (US); Meijun Lu, Hockessin, DE (US)

(73) Assignee: E. I. DU PONT DE NEMOURS AND COMPANY, Wilmington, DE (US)

(21) Appl. No.: 13/239,893

(22) Filed: Sep. 22, 2011

Related U.S. Application Data
(60) Provisional application No. 61/414,478, filed on Nov. 17, 2010.

(51) Int. Cl. H01L 31/18

(52) U.S. Cl. 438/98; 257/E31.126

(57) ABSTRACT

The present invention relates to a chemical etching method for removing portions of material from the photovoltaic laminate of a thin-film photovoltaic panel. The method involves disposing a pre-determined pattern of an etching paste onto the back electrode of the photovoltaic laminate, and then removing the etching paste after a sufficient dwell time.

The method removes portions of the laminate where the etching paste is applied. The method may be used to increase light transmission in thin-film photovoltaic panels for window and sun roof applications.

### FIELD OF THE INVENTION

The present invention relates to a chemical etching method for removing portions of the back electrode and photovoltaic junction from a photovoltaic laminate to increase light transmission creating partial transparency in thin-film photovoltaic panels.

### BACKGROUND

A photovoltaic panel converts radiation energy into electrical energy. Of particular recent interest is the large-scale and cost-effective conversion of solar radiation (sunlight) into electricity using arrays of photovoltaic cells assembled into photovoltaic panels.

Thin-film photovoltaic panels are typically manufactured via a multi-step process, one stage of which is the assembly of a photovoltaic laminate on a substrate. Photovoltaic laminates, which comprise a photovoltaic junction disposed between front and back electrodes, are largely opaque to light transmission, due to the high light absorption of the amorphous silicon junction and presence of a highly reflective metallic back electrode layer. Normally, light impinging on the panel can only transmit through the panel at the narrow scribe breaks where the back electrode/junction stack is divided. As a result, less than 1% of the sunlight is transmitted through the photovoltaic panel. In some applications, it is desirable to be able to conveniently and cost-effectively customize the degree of panel transparency and/or the light transmission pattern for esthetic reasons. For example, for window or sun roof installations of photovoltaic panels, a significant amount of light transmission (20-50%) is often required. It may also be desirable to customize the color or tone of the transmitted light to match or contrast with the interior or exterior surroundings where the partially transparent photovoltaic panel is installed.

A semi-transparent photovoltaic panel has been described in which transparent conductive oxides are used for both the front and back electrodes of the laminate. The degree of transmission can be regulated by adjusting the semiconductor band gap and thickness.

It is also known to fabricate a collection of holes or other polygonal apertures on at least the metallic back electrode layer to facilitate passage of light through the photovoltaic laminate. The junction layer can also be removed at the apertures to enhance light transmission. The apertures can be fabricated by photo-lithography using a photo-resist layer.

It is also known to fabricate a translucent photovoltaic sheet on flexible stainless steel or polymer substrates. When metallic or polymer substrates are used, light must impinge from the film side of the substrate through a transparent conductive oxide (TCO) electrode on the light-facing surface of the laminate, rather than through the substrate. Small round apertures passing through the semiconductor layers and the substrate let a portion of incident light pass through. Aperture formation can be achieved by wet etching, laser drilling or mechanical perforation.

Partially transparent photovoltaic panels equipped with parallel grooves cut into the opaque back electrode or electrode/junction stack have also been disclosed. A lift-off method, etching or laser drilling can be used to create the groove-shaped apertures.

There remains a need for a method to increase light transmission creating partial transparency in thin-film photovoltaic panels that is easy to use, cost effective, efficient and adaptable to the specific application of the photovoltaic panels.

### SUMMARY

One aspect of the invention is a method comprising:
(a) providing a thin-film photovoltaic panel comprising:
   (i) a substrate; and
   (ii) a photovoltaic laminate comprising a front electrode, a back electrode, and a junction layer disposed between the front electrode and the back electrode,
      wherein the front electrode is disposed on the substrate;
(b) disposing an etching paste on the back electrode of the photovoltaic laminate in a predetermined pattern; and
(c) after a predetermined dwell time, removing the etching paste to remove portions of at least the back electrode layer and the junction layer.

This method removes portions of at least the back electrode layer and the junction layer of thin-film photovoltaic panels to increase light transmission by creating partial transparency in the photovoltaic panels.

### BRIEF DESCRIPTION OF THE FIGURES

FIG. 1A is an illustration of a plan view of a thin-film photovoltaic panel after dispensing an etching paste.

FIG. 1B is an illustration of a cross-sectional view of a thin-film photovoltaic panel after dispensing an etching paste.

FIG. 2A is an illustration of a plan view of a thin-film photovoltaic panel after removing a portion of the back electrode layer and the junction layer, showing the resulting apertures in the back electrode/junction stack.

FIG. 2B is an illustration of a cross-sectional view of a thin-film photovoltaic panel after removing a portion of the back electrode layer and the silicon junction layer, showing the resulting apertures in the back electrode/junction stack.

### DETAILED DESCRIPTION

One aspect of this invention is a method for increasing light transmission creating partial transparency in a thin-film photovoltaic panel.

As defined herein, “partial light transparency” means that 5-50% of the incident light is transmitted through the thin-film photovoltaic panel.

According to the present invention, the thin-film photovoltaic panel comprises a substrate and a photovoltaic laminate having a front electrode layer, a junction layer, and a back electrode layer. The front electrode layer is disposed on the substrate and the junction layer is disposed between the front and back electrodes.

Glass or polymer can be employed as the substrate of the thin-film photovoltaic panel. The front electrode layer is disposed on one surface of the substrate and comprises one or more layers of metal such as silver, or metal oxide. Some metal oxide examples include doped tin oxide, zinc oxide, or indium oxide. The back electrode comprises one or more layers of metal such as silver, or metal oxide such as ZnO. At least one of the front electrode and the back electrode is transparent. The thin-film junction layer comprises doped and/or intrinsic (undoped) semiconductors such as silicon and silicon alloys and is disposed between the front and back electrode layers. The silicon and silicon alloys are used in photovoltaic laminates.

In one embodiment, the method comprises dispensing an etching paste onto the back electrode of the photovoltaic laminate in a predetermined pattern, optionally heating the etching paste, removing the etching paste after a predetermined time, and then rinsing the photovoltaic laminate with water and/or an aqueous alkaline solution to remove the etching paste and any residues if present. This method can be used to remove at least the back electrode layer and the junction layer of the photovoltaic laminate in the areas where the etching paste is applied.

The etching paste comprises an acidic etchant and a binder. The acidic etchant comprises at least two acids selected from nitric acid, hydrochloric acid, or hydrofluoric acid. The binder comprises polymeric materials selected from poly(vinyl alcohol), poly(ethylene oxide), polyvinylpyrrolidone (PVP), poloxamers or mixtures thereof. Poloxamers are nonionic triblock copolymers composed of a central hydrophobic chain of polyoxypropylene, flanked by two hydrophilic chains of polyoxyethylene. The etching paste can be applied to the back electrode of the laminate by ink-jet printing or by dispensers selected from nozzles, screens, rollers, brushes, or slot dies.

The etching paste is allowed to remain on the back electrode layer for a predetermined dwell time sufficient to etch through the back electrode and junction layers. The amount of dwell time required depends on the concentration of the etchant and the thickness of the back electrode layer and the junction layer. Typically, less than one minute to 10 minutes is sufficient dwell time. Optionally, the temperature of the etching paste can be increased to reduce the required dwell time. In some embodiment, the temperature of the etching paste during disposing is between 50° C. and 150° C. Higher temperatures may also be used, provided that the temperature does not exceed the thermal stability limits of the substrate or the etching paste.

The photovoltaic laminate is then rinsed with high pressure water or an aqueous alkaline solution in order to wash off the etching paste thus revealing light- transparent apertures. The etched pattern can be customized according to percent transparency and esthetic requirements by modifying the dispensers or the ink-jet print patterns.

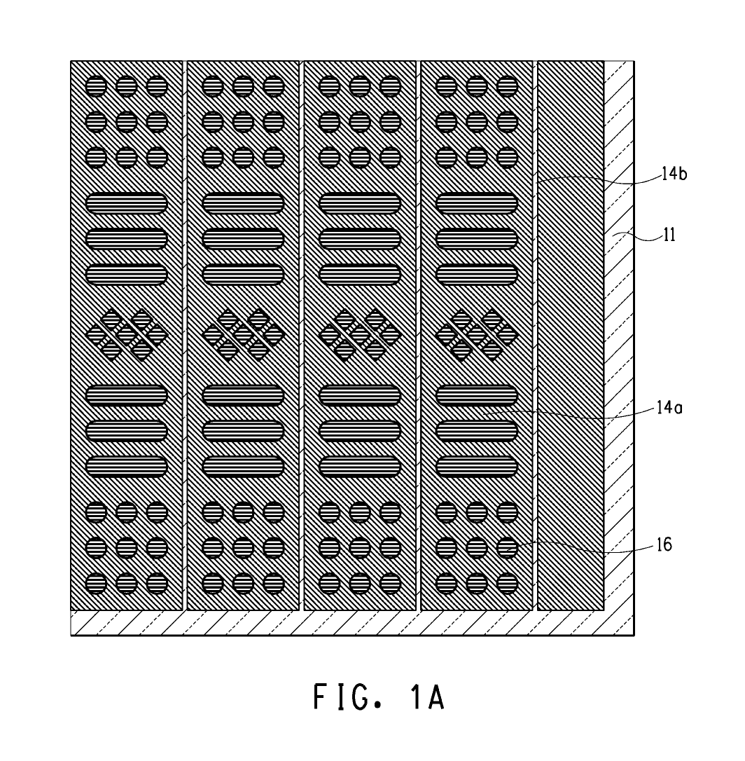

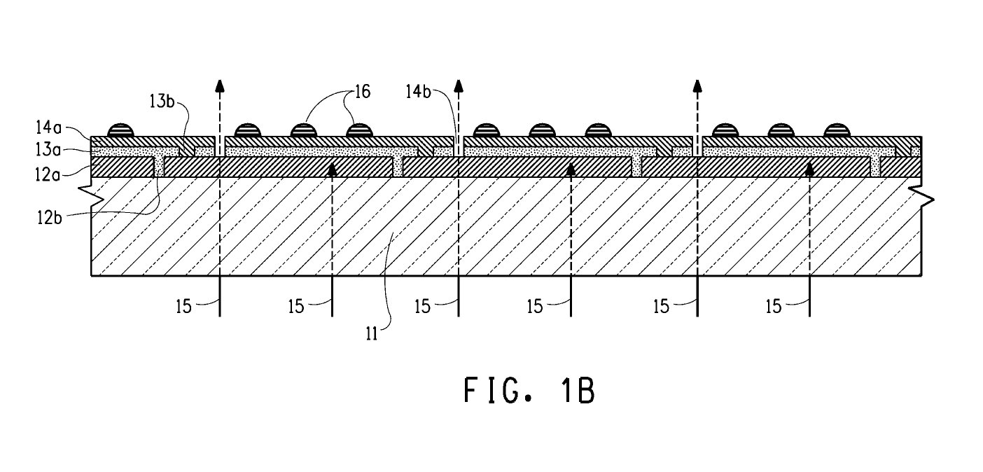

In one embodiment, the front electrode is transparent fluorine-doped tin oxide (FTO), the back electrode is silver, the substrate is glass and the junction layer is amorphous silicon. Due to a high light absorption of the amorphous silicon junction layer and a highly reflective silver back electrode layer, the resulting laminate is largely opaque to light transmission. In a typical photovoltaic panel before etching, light impinging on the panel can only transmit through the panel at the narrow scribe breaks (14b shown in FIG. 1A). Since the scribe break is typically less than 100 microns in width, only a very small percentage of sunlight (<1%) is usually transmitted through the photovoltaic panel.

The amount of light transmitted after etching depends on the etching pattern used and is roughly correlated with the area of the back electrode in contact with etching paste. In some embodiments, the predetermined pattern of etching paste is disposed on 5-50% or 10-40% or 25-35% and all ranges found therewithin of the back electrode.

There are no limits on the types of patterns used. The predetermined pattern can comprise regular geometric shapes (e.g., lines, circles, regular polygons), irregular shapes, or mixtures thereof, arrayed in any pattern.

FIG. 1A illustrates an embodiment of a predetermined pattern and FIG. 1B illustrates a cross-sectional view of the pattern of a thin-film photovoltaic panel onto which etching paste 16 has been deposited in a pre-determined pattern. The panel comprises a substrate 11, a TCO front electrode 12a disposed on the substrate 11, and a plurality of breaks 12b to divide the TCO layer into strips of cell electrodes. Also shown is an amorphous silicon junction layer 13a that is disposed on the TCO front electrode 12a and also makes contact with the substrate through breaks 12b. The junction layer 13a is separated into regions by breaks 13b. A back electrode 14a is disposed on junction layer 13a and makes contact with the front electrode 12a through breaks 13b. Breaks 14b through the junction layer 13a and the back electrode 14a divide the panel into strips of electrical series-connected cells.

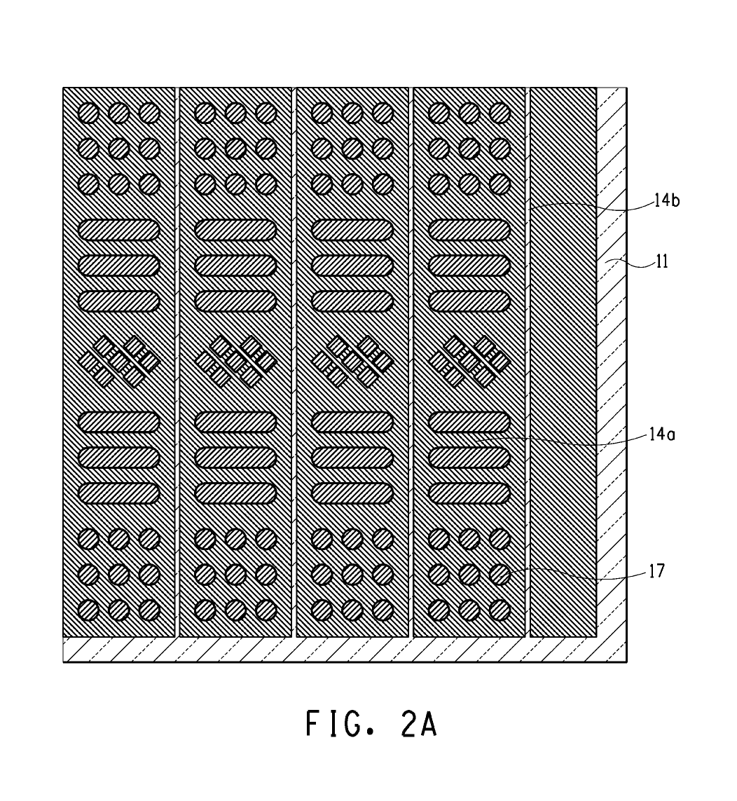

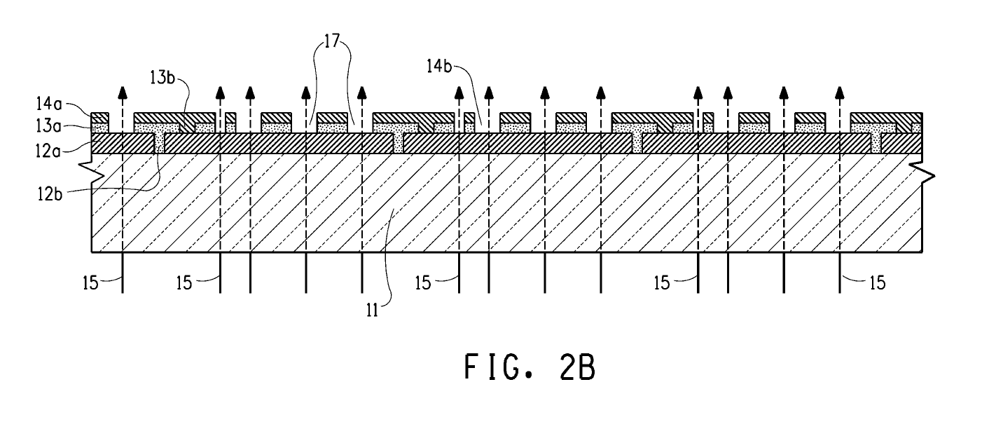

FIGS. 2A and 2B illustrate an embodiment of the predetermined pattern of FIG. 1A and cross-sectional view of the pattern of the panel after removal of etched back electrode and junction layer creating apertures 17. The etching process allows additional light 15 to be transmitted through the photovoltaic panel.

What is claimed is:

1. A method for increasing light transmission in a photovoltaic panel comprising the steps of:
(a) providing a thin-film photovoltaic panel comprising:
(i) a substrate; and
(ii) a photovoltaic laminate comprising a front electrode, a back electrode, and a junction layer disposed between the front electrode and the back electrode,
wherein the front electrode is disposed on the substrate;
(b) disposing an etching paste on the back electrode of the photovoltaic laminate in a predetermined pattern; and
(c) after a predetermined dwell time, removing portions of at least the back electrode layer and the junction layer.

2. The method according to claim 1, wherein the etching paste is disposed using an ink-jet printing method, or is dispensed using one or more dispensers selected from the group consisting of nozzles, screens, rollers, brushes, and slot dies.

3. The method according to claim 1, wherein the etching paste comprises at least two acids selected from the group consisting of nitric acid, hydrochloric acid, and hydrofluoric acid.

4. The method according to claim 1, further comprising heating the etching paste to a temperature between 50° C. to 150° C. after the step of disposing the etching paste.

5. The method according to claim 1, wherein removing the etchant paste comprises rinsing the photovoltaic laminate with water or an aqueous alkaline solution.

6. The method according to claim 1, wherein the front electrode layer is transparent.

7. The method according to claim 1, wherein the back electrode layer is transparent.
